(19) United States
(12) Patent Application Publication
(10) Pub. No.: US 2006/0099765 A1
(43) Pub. Date: May 11, 2006

(54) METHOD TO ENHANCE CMOS TRANSISTOR PERFORMANCE BY INDUCING STRAIN IN THE GATE AND CHANNEL

(75) Inventor: Haining S. Yang, Wappingers Falls, NY (US)

Correspondence Address: FREDERICK W. GIBB, III;GIBB INTELLECTUAL PROPERTY LAW FIRM, LLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 10/904,461

(22) Filed: Nov. 11, 2004

(51) Int. Cl. H01L 21/336

(52) U.S. Cl. 438/301

(57) ABSTRACT

A method of manufacturing complementary metal oxide semiconductor transistors forms different types of transistors such as N-type metal oxide semiconductor (NMOS) transistors and P-type metal oxide semiconductor (PMOS) transistors (first and second type transistors) on a substrate. The method forms an optional oxide layer on the NMOS transistors and the PMOS transistors and then covers the NMOS transistors and the PMOS transistors with a hard material such as a silicon nitride layer. Following this, the method patterns portions of the silicon nitride layer, such that the silicon nitride layer remains only over the NMOS transistors. Next, the method heats the NMOS transistors and then removes the remaining portions of the silicon nitride layer. By creating compressive stress in the gates and tensile stress in the channel regions of the NMOS transistors (NFETs), without creating stress in the gates or channel regions of the PMOS transistors (PFETs), the method improves performance of the NFETs without degrading performance of the PFETs.

### FIELD OF THE INVENTION

This invention is in the field of using strain engineering to improve CMOS transistor device performance. More specifically, it relates to inducing strain in a transistor channel by modulating the stress in the gate.

### DESCRIPTION OF THE RELATED ART

Complementary metal oxide semiconductor (CMOS) device performance may be improved or degraded by the stress applied to the channel region. The stress may be applied by bending the wafer or by placing a stressful material nearby. When tensile stress is applied to N-type metal oxide semiconductor (NMOS) along its channel direction, electron mobility is improved resulting in higher on-current and speed. On the other hand, NMOS performance is degraded when the stress is compressive. P-type metal oxide semiconductor (PMOS) device performance may be improved using a compressive stress to enhance hole mobility. Similarly, PMOS performance will be degraded by a tensile stress applied along the channel direction.

### SUMMARY OF THE INVENTION

The method of manufacturing complementary metal oxide semiconductor transistors presented herein forms different types of transistors such as N-type metal oxide semiconductor (NMOS) transistors and P-type metal oxide semiconductor (PMOS) transistors (first and second type transistors) on a substrate. The invention forms an optional oxide layer on the NMOS transistors and the PMOS transistors and then covers the NMOS transistors and the PMOS transistors with a hard material such as a silicon nitride layer. Following this, the invention patterns portions of the silicon nitride layer, such that the silicon nitride layer remains only over the NMOS transistors. Next, the invention heats the NMOS transistors and then removes the remaining portions of the silicon nitride layer.

The optional oxide layer is used as an etch stop layer to control the process of removing the remaining portions of the silicon nitride layer. The heating process creates compressive stress in the gate, which in turn causes tensile stress in channel regions of transistors that were covered by the silicon nitride layer. Thus, the heating process creates tensile stress in channel regions of the NMOS transistors without causing tensile stress in channel regions of the PMOS transistors. More specifically, during the heating process, volume expansion of gate conductors of the NMOS transistors is restricted, resulting in compressive stress in the gate conductors of the NMOS transistors. The compressive stress in the gate conductors of the NMOS transistors causes tensile stress in channel regions of the NMOS transistors.

In another embodiment, the invention again forms N-type metal oxide semiconductor (NMOS) transistors and P-type metal oxide semiconductor (PMOS) transistors on a substrate. However, in this embodiment, the invention first protects the NMOS transistors and then implants ions into the PMOS transistors to amorphisize the PMOS transistors. Then, the invention performs an annealing process to crystallize the PMOS transistors. After this, the invention protects the PMOS transistors with a mask before implanting irons into the NMOS transistors. Then both the NMOS transistors and the PMOS transistors are covered with a rigid layer and the NMOS transistors and the PMOS transistors are heated. During this heating process, the rigid layer prevents the gate of the NMOS transistors from expanding which creates compressive stress within the gates of the NMOS transistors. Again, this compressive stress within the gates of the NMOS transistors causes tensile stress within the channel regions of the NMOS transistors. After this, the rigid layer is removed and the remaining structures of the transistor are completed.

By creating compressive stress in the gates and tensile stress in the channel regions of the NMOS transistors (NFETs), without creating stress in the gates or channel regions of the PMOS transistors (PFETs), the invention improves performance of the NFETs without degrading performance of the PFETs.

These, and other, aspects and objects of the present invention will be better appreciated and understood when considered in conjunction with the following description and the accompanying drawings. It should be understood, however, that the following description, while indicating preferred embodiments of the present invention and numerous specific details thereof, is given by way of illustration and not of limitation. Many changes and modifications may be made within the scope of the present invention without departing from the spirit thereof, and the invention includes all such modifications.

### BRIEF DESCRIPTION OF THE DRAWINGS

The invention will be better understood from the following detailed description with reference to the drawings, in which:

FIGS. 1-9 are schematic cross-sectional diagrams illustrating different stages in a process of manufacturing a field effect transistor according to a first embodiment;

FIGS. 10-16 are schematic cross-sectional diagrams illustrating different stages in a process of manufacturing a field effect transistor according to a second embodiment;

FIG. 17 is a flow diagram illustrating a preferred method of the invention; and

FIG. 18 is a flow diagram illustrating a preferred method of the invention.

### DETAILED DESCRIPTION OF PREFERRED EMBODIMENTS OF THE INVENTION

The present invention and the various features and advantageous details thereof are explained more fully with reference to the nonlimiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the present invention. The examples used herein are intended merely to facilitate an understanding of ways in which the invention may be practiced and to further enable those of skill in the art to practice the invention. Accordingly, the examples should not be construed as limiting the scope of the invention.

As mentioned above, NMOS performance is improved when the channel region is placed under tensile stress and performance is degraded when the stress is compressive; however, PMOS device performance will be degraded by a tensile stress applied along the channel direction. Therefore, the invention provides a manufacturing method that only creates tensile stress in the NMOS devices without creating tensile stress in PMOS devices. More specifically, the invention generates compressive stress in the transistor gate, and tensile stress is induced in the channel due to the proximity between the gate and channel.

A transistor gate stack generally comprises a gate polysilicon and spacers (of oxide and nitride). When the transistor is annealed at an elevated temperature, the polysilicon grains may grow (or become crystalline if the polysilicon is amorphorized before anneal) resulting in a volume increase in the gate conductor size. However, if the gate stack is covered with a rigid, hard material during the annealing process, the size of the gate cannot increase and compressive stress is created within the gate.

This compressive stress is generated due to different thermal expansion coefficients among the materials in the gate stack in addition to the volume change due to crystallization of poly silicon as mentioned above. As discussed in greater detail below, the invention covers the gate stack with a hard layer (such as a silicon nitride layer) prior to annealing the gate stack. This causes compressive stress within the gate stack. The invention uses hard materials such as silicon nitride, silicon carbide etc. to cover in the gate during the annealing process. The invention advantageously uses such rigid films, as compared to, for example, covering the gate stack with an oxide. When oxides and other films that are not as rigid are used, such films may deform and change shape slightly during the annealing process, yielding to the stress in the gate, and not effectively creating stress within the gate stack. When the transistor gate is annealed and covered by a Si₃N₄ layer, the polysilicon volume change and spacer deformation are limited by the Si₃N₄ layer, inducing high stress in the gate stack after anneal. The stress remains in the gate and channel even after Si₃N₄ is removed.

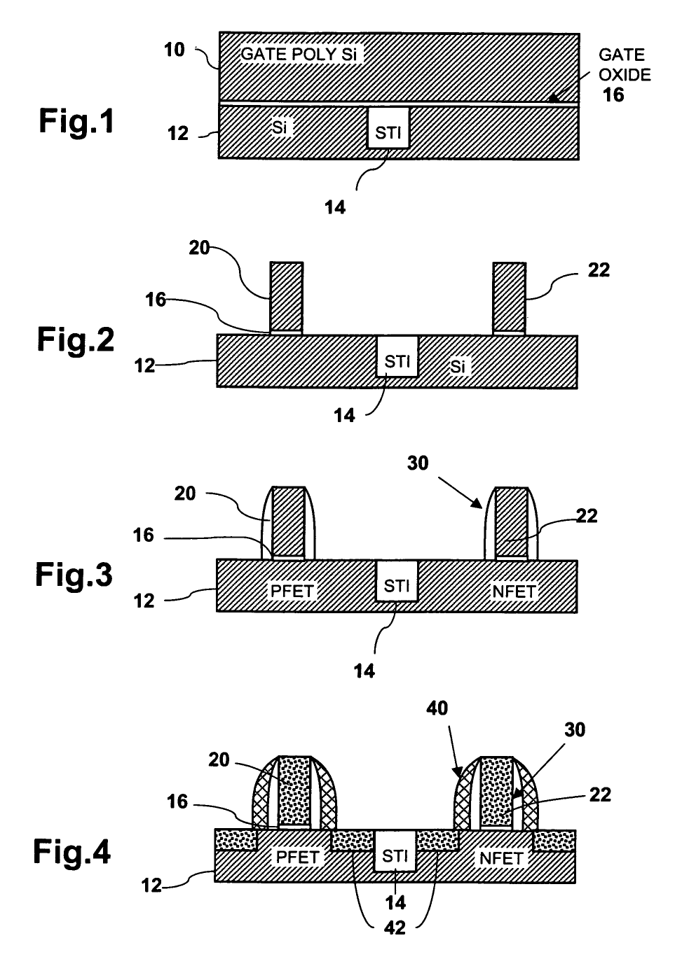

Referring now to the drawings, FIGS. 1-9 are schematic cross-sectional diagrams illustrating different stages in a process of manufacturing a field effect transistor according to a first embodiment and FIGS. 10-16 are schematic cross-sectional diagrams illustrating different stages in a process of manufacturing a field effect transistor according to a second embodiment. Many of the processes and materials used to form the transistors that are covered with the inventive rigid layer are well-known to those ordinary skill in the art (for example, see U.S. Pat. No. 5,670,388 which is incorporated herein by reference). In order to avoid obscuring the salient features of the invention and detailed discussion of such well-known materials and processes is avoided herein.

More specifically, in FIG. 1, polysilicon 10 is deposited on a wafer 12 (such as a silicon wafer) after a shallow trench isolation (STI) region 14 and gate oxide 16 are formed using well-known processing. The polysilicon 10 is patterned to form gate stacks 20, 22 as shown in FIG. 2 using, for example, well-known masking and etching processes. In this example, the gate stack 20 on the left will be used in one type of transistor, such as a P-type transistor (PFET) while the gate stack 22 on the right will be used in an opposite type of transistor such as an N-type transistor (NFET). In FIG. 3, a sidewall spacer 30 is formed on gate stack 20 and extension/halo implants are made for both NFET and PFET.

In FIG. 4, another sidewall spacer 40 is formed and source/drain ion implantations 42 are made. Note that the gate polysilicon 20, 22 (as well as source/drain regions 42) is amorphorized as represented by the different shading in the drawings due to the ion bombardment of the source/drain ion implantation. In this process crystalline or poly-crystalline silicon becomes amorphous silicon that will expand when heated.

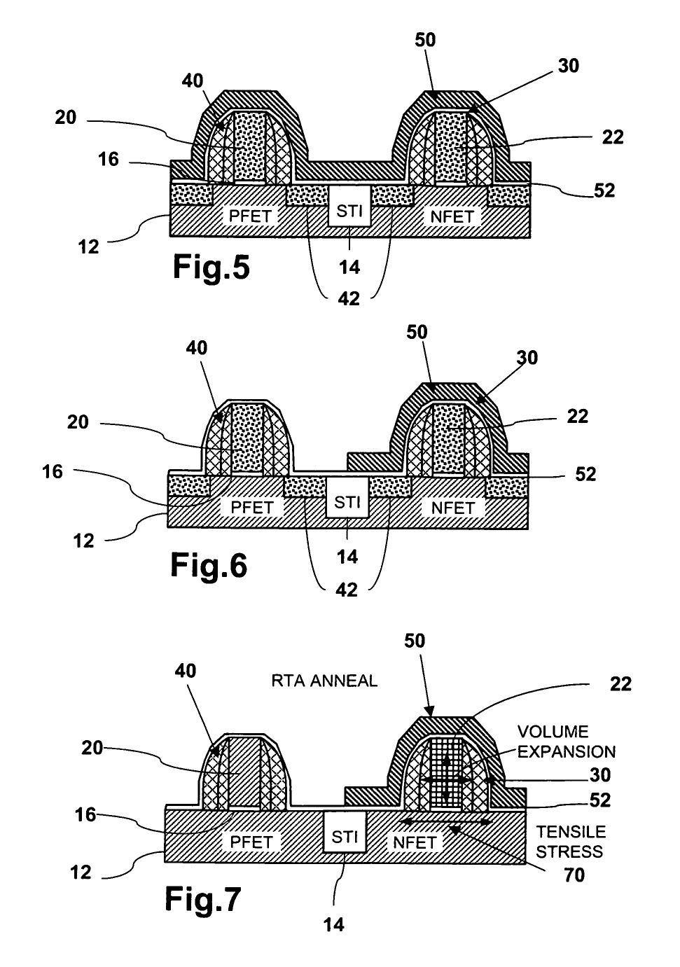

In FIG. 5 a rigid (hard) film 50 such as silicon nitride, silicon carbide, etc. is deposited over the amorphorized wafer 12 using conventional deposition process, such as chemical vapor deposition (CVD), or plasma enhanced CVD process etc. Prior to forming the rigid film 50, an optional etch stop layer 52 such as SiO₂, etc. can be grown or deposited. The material used for the rigid film 50 can comprise any appropriate material that does not substantially deform when the gate conductor 22 tries to expand during the annealing process that is described below. The thickness of the rigid film 50 and the optional etch stop layer 52 can be any thickness that is appropriate, depending upon the manufacturing process being utilized and the specific design of the transistor involved, so long as the rigid film 50 is thick enough to prevent the gate conductor 22 from expanding significantly during the annealing process. For example, the thickness of rigid layer 50 may be in the range of 500 A to 1500 A and the thickness of the etch stop layer may be in the range of 20 A to 50 A.

In FIG. 6 the rigid film 50 is patterned using well-known masking and material removal processes to cover the NFETs only. In FIG. 7, a thermal anneal is performed to activate the implanted dopants and to crystallize the amorphous silicon. The anneal temperature may be, for example, in the range of 700C to 1100C. Note NFET gate 22 becomes stressed because it is encapsulated by rigid layer 50 and cannot significantly expand. As amorphous silicon becomes crystalline, its volume expands. However, because the rigid layer 50 prevents the exterior of the NFET gate 22 from increasing in size, stress builds up within the NFET gate 22. This stress remains within the NFET gate 22 even after the rigid layer 50 is removed because the outer portions of the gate polysilicon 22 will retain their shape and size once the temperature lowers below the annealing temperature. This compressive stress within the NFET gate 22 causes tensile stress in NFET channel region 70. Tensile stress along the channel direction enhances electron mobility and hence improves NFET device performance. The same stress will degrade hole mobility and hence degrade PFET performance. Therefore, in FIG. 6, the rigid layer 50 was removed from the PFET region before the annealing process, to allow the PFET 20 to freely expand.

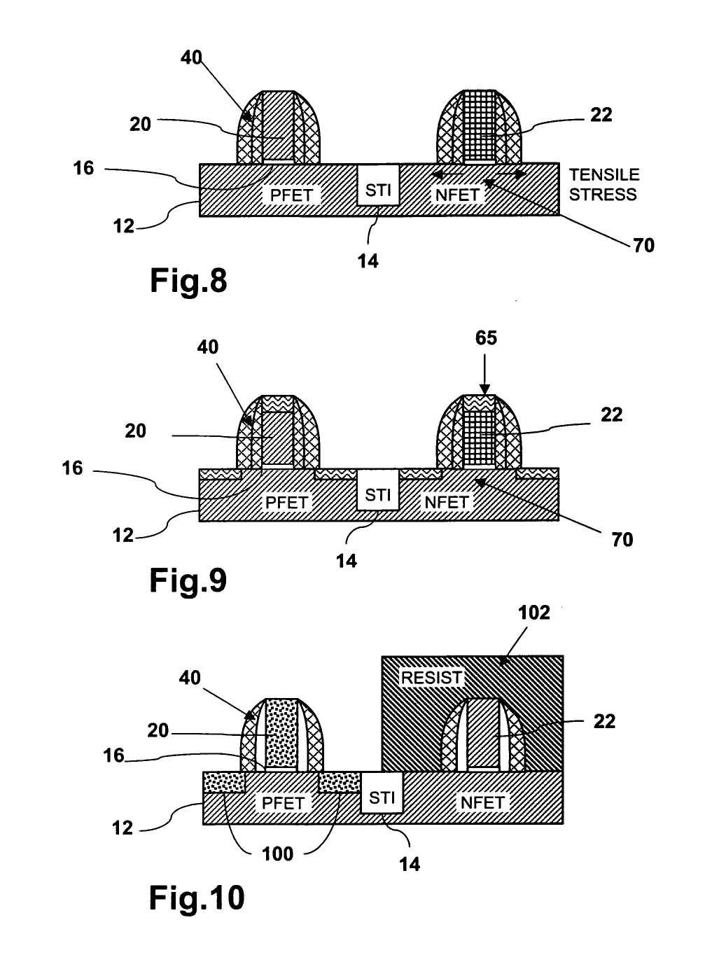

In FIG. 8, and the remaining portions of the rigid layer 50 are removed again using well-known material removal processes. If the etch stop layer 52 was utilized, it can now be removed using, for example a cleaning process that utilizes HF containing chemicals. As mentioned above, they compressive stress remains within the gate 22 and therefore tensile stress remains in the channel 70 even after the rigid film 50 is removed. In FIG. 9, silicide regions 65 are formed on top of gates 20, 22 and on the source/drain regions. Self-aligned silicide (Salicides) can be formed at 300C to 700C using Ni or Co. Non-reacted metal is then stripped away from the wafer. Inter-layer dielectrics (ILD) and interconnects are then formed using well-known processing and materials.

By creating compressive stress in the gates and tensile stress in the channel regions of the NMOS transistors (NFETs), without creating stress in the gates or channel regions of the PMOS transistors (PFETs), the invention improves performance of the NFETs without degrading performance of the PFETs.

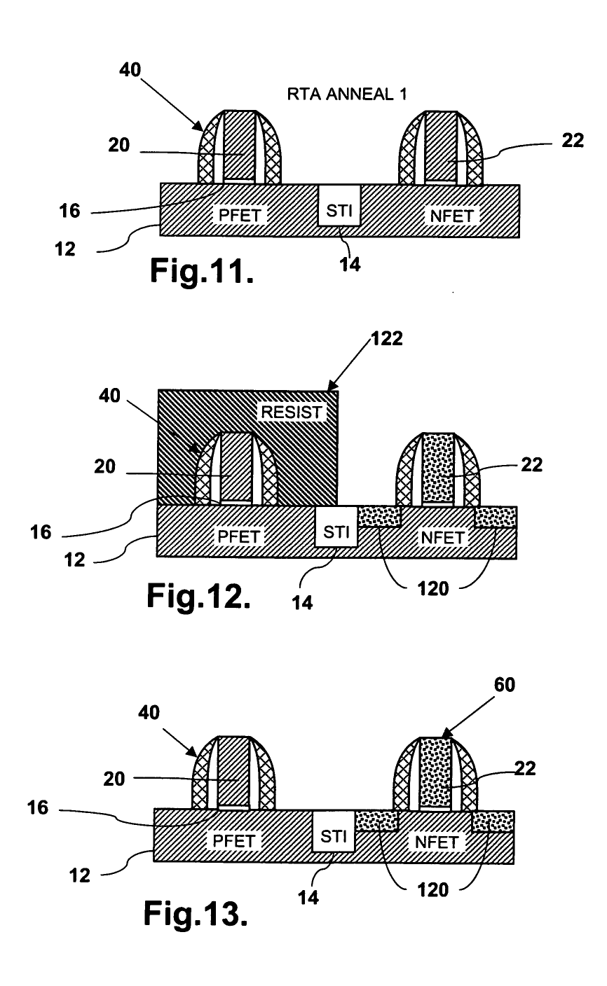

Another embodiment is shown in FIGS. 10-16. More specifically, in FIG. 10, a mask 102, such as a photoresist mask, is patterned and the PFET source/drain implantations 100 are performed while the NFET is covered with photoresist 102. As mentioned, during the implant process, amorphorization is realized in the PFET gate 20. Then, in FIG. 11, the mask 102 is stripped and a heating process, such as a rapid thermal anneal (RTA) is performed to crystallize the PFET amorphous silicon 20. This crystallization process of the gate 20 will cause the gate 20 to expand and, because there is no rigid layer over the gate 20, this expansion does not create compressive stress within the gate 20.

In FIG. 12, another photoresist mask 122 is patterned to cover the PFETs and a second ion implantation process is performed on the exposed NFETs to form the source/drain regions 120 and to amorphisize the gate conductor 22. Then, in FIG. 13, the photoresist 122 is again stripped. Note that because the PFETs were protected by a mask 122, only the NFETs have amorphous silicon regions remaining.

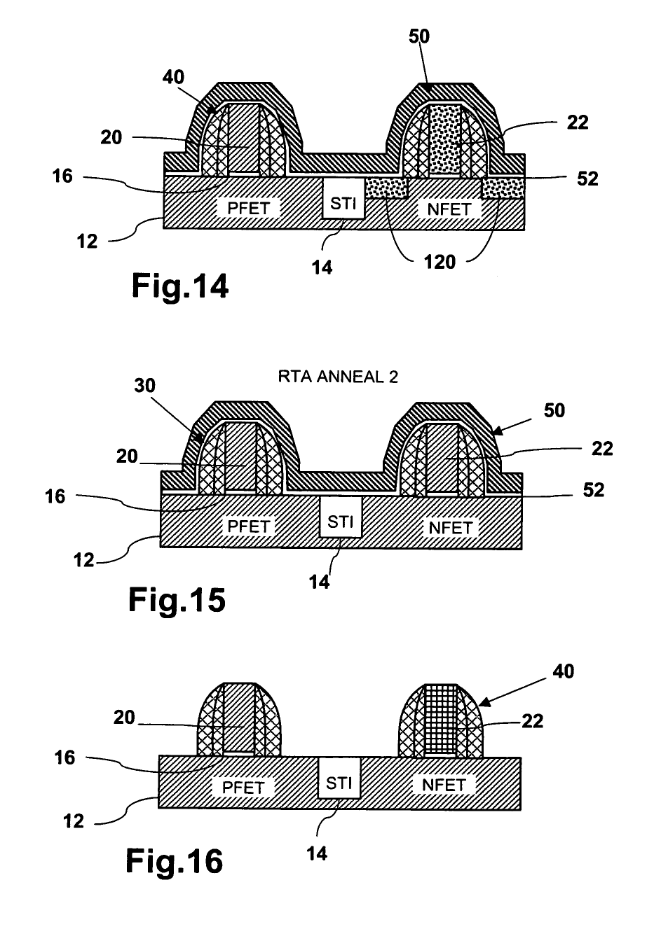

In FIG. 14, the rigid layer 50 and the optional oxide layer 52 are formed as discussed above. Then, in FIG. 15, a thermal anneal is performed to activate implanted dopants and to crystallize amorphous silicon. Again, the anneal temperature may be in the range of, for example, 700C to 1100C. Note that only the NFET gate poly 22 becomes compressively stressed because the PFET gate 20 did not contain amorphous state material that was within the gate 22. Then, in FIG. 16, the rigid film 50 and optional oxide film 52 are removed and the wafer is ready for salicidation, as discussed above.

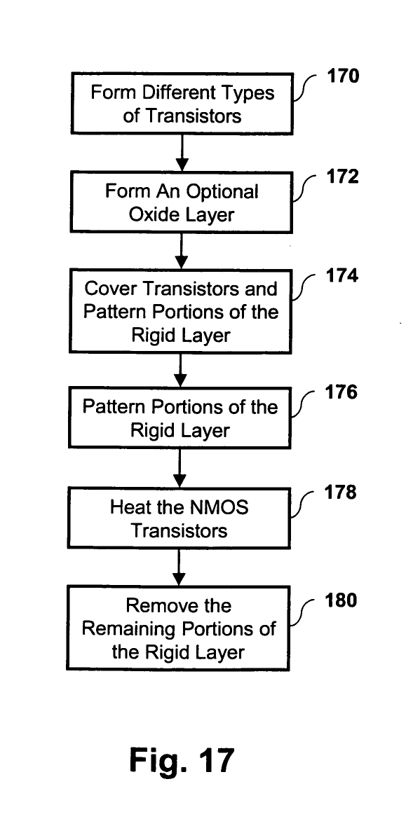

FIG. 17 shows the first embodiment in flow chart form. More specifically, in item 170 the method forms different (e.g., opposite) types of transistors such as N-type metal oxide semiconductor (NMOS) transistors and P-type metal oxide semiconductor (PMOS) transistors (first and second type transistors) on a substrate. In item 172, the invention forms an optional oxide layer on the NMOS transistors and the PMOS transistors and then covers the NMOS transistors and the PMOS transistors with a rigid material such as a silicon nitride layer in item 174. Following this, the invention patterns portions of the rigid layer in item 176, such that the rigid layer remains only over the NMOS transistors. Next, the invention heats the NMOS transistors in item 178 and then removes the remaining portions of the rigid layer in item 180.

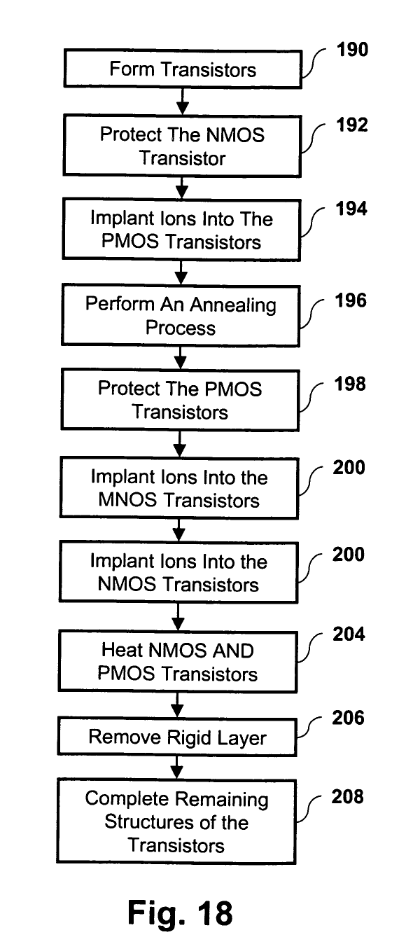

In the second embodiment shown in flow chart form in FIG. 18, the invention again forms N-type metal oxide semiconductor (NMOS) transistors and P-type metal oxide semiconductor (PMOS) transistors on a substrate in item 190. However, in this embodiment, the invention first protects the NMOS transistors in item 192 and then implants ions into the PMOS transistors to amorphisize the PMOS transistors in item 194. Then, the invention performs an annealing process to crystallize the PMOS transistors in item 196. After this, the invention protects the PMOS transistors with a mask in item 198 before implanting ions into the NMOS transistors in item 200. Then, both the NMOS transistors and the PMOS transistors are covered with a rigid layer in item 202 and the NMOS transistors and the PMOS transistors are heated in item 204. During this heating process, the rigid layer prevents the gate of the NMOS transistors from expanding which creates compressive stress within the gates of the NMOS transistors. Again, this compressive stress within the gates of the NMOS transistors causes tensile stress within the channel regions of the NMOS transistors. After this, the rigid layer is removed in item 206 and the remaining structures of the transistor are completed in item 208.

The heating process creates compressive stress in the gate, which in turn causes tensile stress in channel regions of transistors that were covered by the silicon nitride layer. Thus, the heating process creates tensile stress in channel regions of the NMOS transistors without causing tensile stress in channel regions of the PMOS transistors. More specifically, during the heating process, volume expansion of gate conductors of the NMOS transistors is restricted, resulting in compressive stress in the gate conductors of the NMOS transistors. The compressive stress in the gate conductors of the NMOS transistors causes tensile stress in channel regions of the NMOS transistors. By creating compressive stress in the gates and tensile stress in the channel regions of the NMOS transistors (NFETs), without creating stress in the gates or channel regions of the PMOS transistors (PFETs), the invention improves performance of the NFETs without degrading performance of the PFETs.

While the invention has been described in terms of preferred embodiments, those skilled in the art will recognize that the invention can be practiced with modification within the spirit and scope of the appended claims.

What is claimed is:

1. A method of manufacturing a transistor, said method comprising:
forming a transistor on a substrate;
covering said transistor with a rigid layer; and
heating said transistor to create tensile stress in said transistor.

2. The method according to claim 1, further comprising forming an oxide layer on said transistor prior to forming said rigid layer.

3. The method according to claim 1, wherein said rigid layer comprises at least one of silicon nitride and silicon carbide.

4. The method according to claim 1, implanting ions into a gate of further comprising said transistor before covering said transistor with said rigid layer.

5. The method according to claim 1, wherein said heating process creates tensile stress in channel regions of said transistor without causing tensile stress in channel regions of other transistors that are not covered by said rigid layer.

6. The method according to claim 1, wherein during said heating process, volume expansion of gate conductors of first-type transistor is restricted, resulting in compressive stress in said gate conductors of said first-type transistor.

7. The method according to claim 6, wherein said compressive stress in said gate conductors of said first-type transistor causes tensile stress in channel regions of said first-type transistor.

8. A method of manufacturing complementary transistors, said method comprising:
forming first-type transistors and second-type transistors on a substrate;
covering said first-type transistors and said second-type transistors with a rigid layer;
patterning portions of said rigid layer, such that said rigid layer remains only over said first-type transistors; and
heating said first-type transistors.

9. The method according to claim 8, further comprising forming an oxide layer on said first-type transistors and said second-type transistors prior to forming said rigid layer on said first-type transistors and said second-type transistors.

10. The method according to claim 8, wherein said rigid layer comprises at least one of silicon nitride and silicon carbide.

11. The method according to claim 8, wherein said heating process creates tensile stress in channel regions of transistors covered by said rigid layer.

12. The method according to claim 8, wherein said heating process creates tensile stress in channel regions of said first-type transistors without causing tensile stress in channel regions of said second-type transistors.

13. The method according to claim 8, wherein during said heating process, volume expansion of gate conductors of said first-type transistors is restricted, resulting in compressive stress in said gate conductors of said first-type transistors.

14. The method according to claim 13, wherein said compressive stress in said gate conductors of said first-type transistors causes tensile stress in channel regions of said first-type transistors.

15. A method of manufacturing complementary metal oxide semiconductor transistors, said method comprising:
forming N-type metal oxide semiconductor (NMOS) transistors and P-type metal oxide semiconductor (PMOS) transistors on a substrate;
covering said NMOS transistors and said PMOS transistors with a rigid layer;
patterning portions of said rigid layer, such that said rigid layer remains only over said NMOS transistors; and
heating said NMOS transistors.

16. The method according to claim 15, further comprising forming an oxide layer on said NMOS transistors and said PMOS transistors prior to forming said rigid layer on said NMOS transistors and said PMOS transistors.

17. The method according to claim 15, wherein said rigid layer comprises at least one of silicon nitride and silicon carbide.

18. The method according to claim 15, wherein said heating process creates tensile stress in channel regions of transistors covered by said rigid layer.

19. The method according to claim 15, wherein said heating process creates tensile stress in channel regions of said NMOS transistors without causing tensile stress in channel regions of said PMOS transistors.

20. The method according to claim 15, wherein during said heating process, volume expansion of gate conductors of said NMOS transistors is restricted, resulting in compressive stress in said gate conductors of said NMOS transistors.

21. The method according to claim 20, wherein said compressive stress in said gate conductors of said NMOS transistors causes tensile stress in channel regions of said NMOS transistors.

22. A method of manufacturing complementary transistors, said method comprising:
forming first-type transistors and second-type transistors on a substrate;
protecting said second-type transistors with a mask;
implanting ions into said first-type transistors;
covering said first-type transistors and said second-type transistors with a rigid layer; and
heating said first-type transistors and said second-type transistors.

23. The method according to claim 22, further comprising forming an oxide layer on said first-type transistors and said second-type transistors prior to forming said rigid layer on said first-type transistors and said second-type transistors.

24. The method according to claim 22, wherein said rigid layer comprises at least one of silicon nitride and silicon carbide.

25. The method according to claim 22, wherein said heating process creates tensile stress in channel regions of said first-type transistors.

26. The method according to claim 22, wherein said heating process creates tensile stress in channel regions of said first-type transistors without causing tensile stress in channel regions of said second-type transistors.

27. The method according to claim 22, wherein during said heating process, volume expansion of gate conductors of said first-type transistors is restricted, resulting in compressive stress in said gate conductors of said first-type transistors.

28. The method according to claim 27, wherein said compressive stress in said gate conductors of said first-type transistors causes tensile stress in channel regions of said first-type transistors.

29. A method of manufacturing complementary metal oxide semiconductor transistors, said method comprising:
forming N-type metal oxide semiconductor (NMOS) transistors and P-type metal oxide semiconductor (PMOS) transistors on a substrate;
protecting said PMOS transistors with a mask;
implanting ions into said NMOS transistors;
covering said NMOS transistors and said PMOS transistors with a rigid layer; and
heating said NMOS transistors and said PMOS transistors.

30. The method according to claim 29, further comprising forming an oxide layer on said NMOS transistors and said PMOS transistors prior to forming said rigid layer on said NMOS transistors and said PMOS transistors.

31. The method according to claim 29, wherein said rigid layer comprises at least one of silicon nitride and silicon carbide.

32. The method according to claim 29, wherein said heating process creates tensile stress in channel regions of transistors covered by said rigid layer.

33. The method according to claim 29, wherein said heating process creates tensile stress in channel regions of said NMOS transistors without causing tensile stress in channel regions of said PMOS transistors.

34. The method according to claim 29, wherein during said heating process, volume expansion of gate conductors of said NMOS transistors is restricted, resulting in compressive stress in said gate conductors of said NMOS transistors.

35. The method according to claim 29, wherein said compressive stress in said gate conductors of said NMOS transistors causes tensile stress in channel regions of said NMOS transistors.
